(19) United States
(12) Patent Application Publication
(10) Pub. No.: US 2008/0132046 A1
(43) Pub. Date: Jun. 5, 2008

(54) Plasma Doping With Electronically Controllable Implant Angle

(75) Inventor: Steven Raymond Walther, Andover, MA (US)

Correspondence Address: RAUSCHENBACH PATENT LAW GROUP, LLC, P.O. BOX 387, BEDFORD, MA, 01730, US

(73) Assignee: VARIAN SEMICONDUCTOR EQUIPMENT ASSOCIATES, INC., Gluocester, MA (US)

(21) Appl. No.: 11/566,418

(22) Filed: Dec. 4, 2006

(51) Int. Cl. H01L 21/26; H01L 21/42

(52) U.S. Cl. 438/513

(57) ABSTRACT

A plasma doping apparatus includes a chamber and a plasma source that generates ions from a dopant gas. A platen is positioned in the chamber adjacent to the plasma source that supports a wafer for plasma doping. A deflection grid comprising a first and second deflection electrode is positioned in the chamber between the plasma source and the platen. The deflection grid deflects ions with an angle that is proportional to a voltage difference between the first and the second deflection electrodes.

The section headings used herein are for organizational purposes only and should not to be construed as limiting the subject matter described in the present application.

### BACKGROUND

Conventional beam-line ion implanters accelerate ions with an electric field. The accelerated ions are filtered according to their mass-to-charge ratio to select the desired ions for implantation. Some conventional beam-line ion implanters control the angle of implant by moving the target relative to the beam. Such systems have relatively low throughput.

Recently plasma doping (sometimes referred to as PLAD) and plasma immersion ion implantation (sometimes referred to as PIII) systems have been developed to meet the doping requirements of some modern electronic and optical devices. These systems immerse the target in a plasma containing dopant ions and biases the target with a series of negative voltage pulses. The electric field within the plasma sheath accelerates ions towards the target which implants the ions into the target surface.

Some known PLAD and PIII systems control the angle of implant by magnetic deflection. However, such systems are typically limited to relatively low ion implant energies. Furthermore, such systems require large magnetic fields that necessitate the use of large magnets that can significantly increase the size of the ion implantation system. Other known PLAD and PIII systems control the angle of implant by using a moving grid structure. For example, see U.S. patent application Ser. No. 10/908,009, filed Apr. 25, 2005, entitled “Tilted Plasma Doping,” which is assigned to the present assignee. The entire specification of U.S. patent application Ser. No. 10/908,009 is incorporated herein by reference.

### BRIEF DESCRIPTION OF THE DRAWINGS

The aspects of this invention may be better understood by referring to the following description in conjunction with the accompanying drawings, in which like numerals indicate like structural elements and features in various figures. The drawings are not necessarily to scale. The skilled artisan will understand that the drawings, described below, are for illustration purposes only. The drawings are not intended to limit the scope of the present teachings in any way.

FIG. 1 illustrates one embodiment of a plasma doping apparatus with an electrostatic grid having voltage controlled deflection according to the present invention.

FIG. 2 illustrates a schematic diagram of a deflection grid according to the present invention.

FIG. 3A illustrates simulated potential distributions for the deflection grid described in connection with FIG. 2.

FIG. 3B illustrates simulated ion trajectories corresponding to the simulated potential distributions for the deflection grid described in connection with FIG. 3A.

### DETAILED DESCRIPTION

While the present teachings are described in conjunction with various embodiments and examples, it is not intended that the present teachings be limited to such embodiments. On the contrary, the present teachings encompass various alternatives, modifications and equivalents, as will be appreciated by those of skill in the art.

For example, the methods and apparatus of the present invention can be applied to other ion beam application, such as ion beam etching and other materials processing applications, and are not limited to plasma doping. Also, one skilled in the art will appreciate that the apparatus and methods of the present invention are not limited to the plasma source design described herein. Any type of plasma source can be used with the present invention.

It should be understood that the individual steps of the methods of the present invention may be performed in any order and/or simultaneously as long as the invention remains operable. Furthermore, it should be understood that the apparatus of the present invention can include any number or all of the described embodiments as long as the invention remains operable.

One aspect of the present invention relates to performing ion implants with non-zero implant angles. It is sometimes desirable to have both the throughput capability of plasma doping and the ability to control the angle of the implant. It is also desirable to control the angle of implant in a way that does not introduce asymmetries caused by variations of the ion path length from the grid to the wafer.

Another aspect of the present invention relates to performing single multi-step ion implants with at least two different implant angles. The plasma doping apparatus of the present invention can perform multi-step ion implants having at least two different implant angles by simply varying the voltage applied to an electrostatic deflection grid so that the applied voltages correspond to the desired implant angles as a function of time.

In one embodiment of the invention, a plasma doping system according to the present invention achieves control of the ion incidence angle of the implant by using a grid that includes rods of alternating voltages. In this embodiment, the potential difference between adjacent rods controls the ion incidence angle. Therefore, one feature of the present invention is that the ion incidence angle of a plasma doping system according to the present invention can be controlled electronically. Electronic adjustment of the ion incidence angle is much faster and much more accurate than mechanical angle adjusting means used in known systems.

In another embodiment, a plasma doping system according to the present invention achieves control over the uniformity of the ion beam flux by using a grid that includes rods of alternating voltages. In this embodiment, the ion implant can be performed at both a zero angle of incidence and a non-zero angle of incidence. Therefore, another feature of the present invention is that the uniformity of ion beam flux in a plasma doping system can be controlled electronically. Electronic adjustment of the ion beam flux uniformity is relatively fast and accurate and can be performed in-situ.

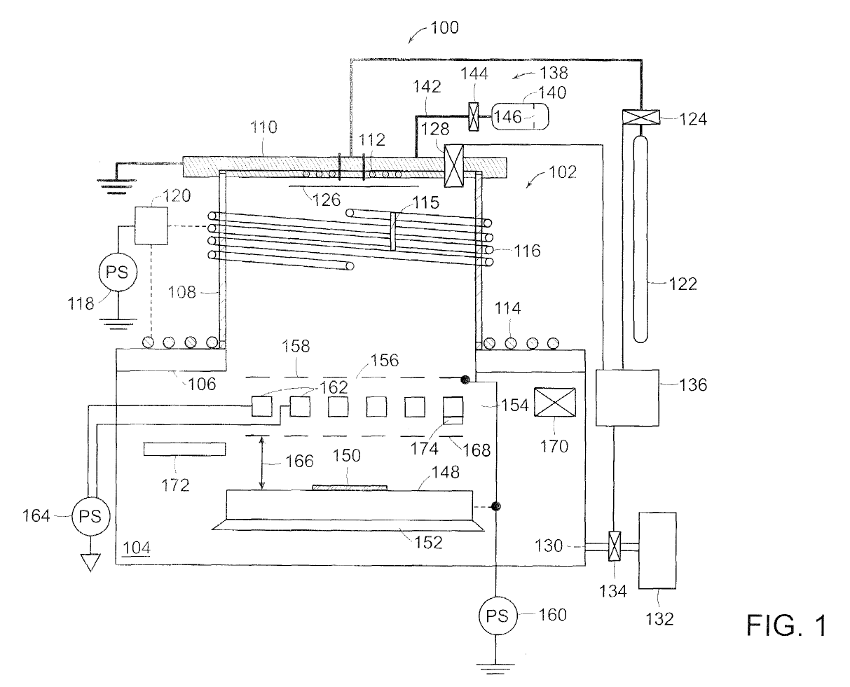

FIG. 1 illustrates one embodiment of a plasma doping apparatus 100 with an electrostatic grid having voltage controlled deflection according to the present invention. The plasma doping apparatus 100 includes a plasma source 102 that is attached to a process chamber 104. The plasma source 102 shown in FIG. 1 is a RF inductively coupled plasma source that is described in more detail in U.S. patent application Ser. No. 10/905,172, filed on Dec. 20, 2004, which is assigned to the present assignee. The entire specification of U.S. patent application Ser. No. 10/905,172 is incorporated herein by reference.

In other embodiments of the invention, the plasma source 102 can be any plasma source that creates the required density of dopant ions. For example, in other embodiments, the plasma source 102 can be an inductively coupled plasma source, a capacitively coupled plasma source, a toroidal plasma source, a helicon plasma source, a DC plasma source (such as a glow discharge plasma source), a remote plasma source, and a downstream plasma source. These plasma sources can operate in either a continuous mode or a pulsed mode.

The plasma source 102 shown in FIG. 1 includes a first section 106 formed of a dielectric material that extends in a horizontal direction. A second section 108 is formed of a dielectric material that extends a height from the first section 106 in a vertical direction. In the embodiment shown in FIG. 1, the second section 108 is formed in a cylindrical shape. It is understood that one skilled in the art will appreciate that the first section 106 does not need to extend in exactly a horizontal direction and the second section 108 does not need to extend in exactly a vertical direction.

The dimensions of the first and the second sections 106, 108 of the plasma source 102 can be selected to improve the uniformity of plasmas generated in the plasma source 102. In one embodiment, a ratio of the height of the second section 108 in the vertical direction to the length across the second section 108 in the horizontal direction is adjusted to achieve a more uniform plasma. For example, in one particular embodiment, the ratio of the height of the second section 108 in the vertical direction to the length across the second section 108 in the horizontal direction is about between 1.5 and 5.5.

The dielectric materials in the first and second sections 106, 108 provide a medium for transferring the RF power from the RF antenna to a plasma inside the plasma source 102. In one embodiment, the dielectric material used to form the first and second sections 106, 108 is a high purity ceramic material that is chemically resistant to the dopant gases and that has good thermal properties. For example, in some specific embodiments, the dielectric material is 99.6% Al₂O₃ or AlN. In other specific embodiments, the dielectric material is Yittria and YAG or silicon nitride (Si₃N₄).

A top section 110 of the plasma source 102 is formed of a conductive material that extends across the top of the second section 108 in the horizontal direction. In some embodiments, the conductive material is aluminum or silicon. The material used to form the top section 110 is typically chosen to be chemically resistant to the dopant gases. The conductivity of the material used to form the top section 110 can be chosen to be high enough to dissipate a substantial portion of the heat load and to minimize charging effects that results from secondary electron emission.

In one embodiment, the top section 110 is coupled to the second section 108 with a high temperature halogen resistant O-rings that are made of fluoro-carbon polymer, such as an O-ring formed of Chemrz and/or Kalrex materials. The top section 110 is typically mounted to the second section 108 in a manner that minimizes compression on the second section 108, but that also provides enough compression to seal the top section 110 to the second section 108.

Some plasma doping processes generate a considerable amount of non-uniformly distributed heat on the inner surfaces of the plasma source 102 because of secondary electron emissions. The non-uniformly distributed heat creates temperature gradients on the inner surfaces of the plasma source 102 that can be high enough to cause thermal stress points within the plasma source 102 that can result in a failure. Some embodiments improve heat distribution by including a cooling system that regulates the temperature of the top section 110 in order to dissipate the heat load generated during processing. The cooling system can be a fluid cooling system that includes cooling passages 112 in the top section 110 that circulates a liquid coolant from a coolant source.

A RF antenna is positioned proximate to at least one of the first section 106 and the second section 108 of the plasma source 102. The plasma doping apparatus 100 illustrated in FIG. 1 illustrates a planar coil antenna 114 positioned adjacent to the first section 106 of the plasma source 102 and a helical coil antenna 116 surrounding the second section 108 of the plasma source 102. However, the plasma source 102 can have many different antenna configurations.

At least one of the planar coil antenna 114 and the helical coil antenna 116 is an active antenna. The term “active antenna” is herein defined as an antenna that is driven directly by a power supply. In other words, a voltage generated by a power supply is directly applied to an active antenna. In some embodiments, at least one of the planar coil antenna 114 and the helical coil antenna 116 is formed such that it can be liquid cooled. Cooling at least one of the planar coil antenna 114 and the helical coil antenna 116 will reduce temperature gradients caused by the RF power propagating in the RF antennas 114, 116.

In some embodiments, one of the planar coil antenna 114 and the helical coil antenna 116 is a parasitic antenna. The term “parasitic antenna” is defined herein to mean an antenna that is in electromagnetic communication with an active antenna, but that is not directly connected to a power supply. In other words, a parasitic antenna is not directly excited by a power supply, but rather is excited by an active antenna. In some embodiments of the invention, one end of the parasitic antenna is electrically connected to ground potential in order to provide antenna tuning capabilities. In this embodiment, the parasitic antenna includes a coil adjuster 115 that is used to change the effective number of turns in the parasitic antenna coil. Numerous different types of coil adjusters, such as a metal short, can be used.

A RF power supply 118 is electrically connected to at least one of the planar coil antenna 114 and the helical coil antenna 116. The RF power supply 118 is electrically coupled to at least one of the RF antennas 114, 116 by an impedance matching network 120 that maximizes the power transferred from the RF power supply 118 to the RF antennas 114, 116. Dashed lines from the output of the impedance matching network 120 to the planar coil antenna 114 and the helical coil antenna 116 are shown to indicate that electrical connections can be made from the output of the impedance matching network 120 to either or both of the planar coil antenna 114 and the helical coil antenna 116.

A gas source 122 is coupled to the plasma source 102 through a proportional valve 124. In some embodiments, a gas baffle 126 is used to disperse the gas into the plasma source 102. A pressure gauge 128 measures the pressure inside the plasma source 102. An exhaust port 130 in the process chamber 104 is coupled to a vacuum pump 132 that evacuates the process chamber 104. An exhaust valve 134 controls the exhaust conductance through the exhaust port 130. A gas pressure controller 136 is electrically connected to the proportional valve 124, the pressure gauge 128, and the exhaust valve 134. The gas pressure controller 136 maintains the desired pressure in the plasma source 102 and the process chamber 104 by controlling the exhaust conductance with the exhaust valve 134 and controlling the dopant gas flow rate with the proportional valve 124 in a feedback loop that is responsive to the pressure gauge 128.

In some embodiments, a ratio control of trace gas species is provided by a mass flow meter (not shown) that is coupled in-line with the dopant gas that provides the primary dopant gas species. Also, in some embodiments, a separate gas injection means (not shown) is used for in-situ conditioning species. For example, silicon doped with an appropriate dopant can be used to provide a uniform coating in the process chamber 104 that reduces contaminants. Furthermore, in some embodiments, a multi-port gas injection means (not shown) is used to provide gases that cause neutral chemistry effects that result in across wafer variations.

In some embodiments, the plasma doping apparatus 100 includes a plasma igniter 138. Numerous types of plasma igniters can be used with the plasma doping apparatus of the present invention. In one embodiment, the plasma igniter 138 includes a reservoir 140 of strike gas, which is a highly-ionizable gas, such as argon (Ar), which assists in igniting the plasma. The reservoir 140 is coupled to the plasma chamber 104 with a high conductance gas connection 142. A burst valve 144 isolates the reservoir 140 from the process chamber 104. In another embodiment, a strike gas source is plumbed directly to the burst valve 144 using a low conductance gas connection. In some embodiments, a portion of the reservoir 140 is separated by a limited conductance orifice 146 or metering valve that provides a steady flow rate of strike gas after the initial high-flow-rate burst.

A platen 148 is positioned in the process chamber 104 a height below the top section 110 of the plasma source 102. The platen 148 holds a wafer 150, such as a substrate or wafer, for ion implantation. In many embodiments, the wafer 150 is electrically connected to the platen 148. In the embodiment shown in FIG. 1, the platen 148 is parallel to the plasma source 102. However, in one embodiment of the present invention, the platen 148 is tilted with respect to the plasma source 102.

In one embodiment, the platen 148 is mechanically coupled to a movable stage 152 that translates, scans, or oscillates the wafer 150 in at least one direction. In one embodiment, the movable stage 152 is a dither generator or an oscillator that dithers or oscillates the wafer 150. The translation, dithering, and/or oscillation motions can reduce or eliminate shadowing effects and can improve the uniformity of the ion beam flux impacting the surface of the wafer 150.

A deflection grid 154 is positioned in the process chamber 104 between the plasma source 102 and the platen 148. In some embodiments, more than one deflection grid 154 is used. The term “grid” is defined herein as a structure that forms a barrier to the plasma generated in the plasma source 102 and that also defines passages through which the ions in the plasma pass through when the grid is properly biased. The terms “deflection grid” and “deflector grid” are defined herein as a grid that deflects the ions passing from the plasma through holes or apertures at a certain angle.

The deflection grid 154 includes a plurality of apertures 156 in a top section 158 that passes ions from the plasma source 102 to the platen 148. A bias voltage power supply 160 is electrically connected to the top section 158 of the deflection grid 154. The bias voltage power supply 160 can be a DC power supply, a pulsed power supply, or a RF power supply. The voltage applied to the top section 158 of the deflection grid 154 defines the energy of the ion implant. In some embodiments, the bias voltage power supply 160 is also used to bias the wafer 150. In other embodiments, a separate bias voltage power supply is electrically connected to the wafer 150. One skilled in the art will appreciate that the plasma doping apparatus of FIG. 1 has many different possible biasing configurations.

The deflection grid 154 includes at least two deflection electrodes 162. In some embodiments, the deflection electrodes 162 are in the shape of a rod. The at least two deflection electrodes 162 are electrically connected to a deflection voltage power supply 164 so that they generate electric fields that deflect ions propagating through the grid 154. In various embodiments, the individual deflection electrodes are biased with at least two different bias voltages as described herein. In the embodiment shown in FIG. 1, the at least two deflection electrodes 162 are electrically connected to a single power supply that has at least two separate electrical outputs. In other embodiments, some of the at least two deflection electrodes 162 are electrically connected to separate independent power supplies.

In some embodiments, at least one of the deflection electrodes 162 includes a conduit for passing cooling fluid. For example, water or other cooling liquids can be passed through the conduit to control the operating temperature of the deflection grid 154. Controlling the operating temperature of the deflection grid 154 is important for some applications because it will prevent the deflection grid 154 from distorting, which can change the angle of ion deflection.

In the embodiment shown in FIG. 1, the deflection grid 154 includes a plurality of deflection electrodes. In this embodiment, two different voltages are applied to the plurality of deflection electrodes in a spatially alternating pattern as described further herein. For example, voltage V1 can be applied to odd numbered deflection electrodes and voltage V2 can be applied to even numbered deflection electrodes. In this embodiment, the angle of deflection from a normal angle of incidence experienced by the ions accelerated through the grid deflection grid 154 is proportional to the difference between voltage V1 and V2.

In one embodiment, the distance 166 between the exit surface 168 of the deflection grid 154 and the top surface of the platen 148 is adjustable so as to improve the uniformity of the ion implantation dose. Also, in one embodiment, the thickness of the deflection grid 154 is chosen to improve uniformity and/or to achieve certain predetermined angles of ion deflection. Also, in some embodiments, the distance between the apertures 156 in the top section 158 can also be chosen to improve uniformity. In addition, in some embodiments, the region between the deflection grid 154 and the platen 148 can be dimensioned to reduce the number of ion collisions.

In one embodiment, the deflection grid 154 is mechanically coupled to a movable stage 152. The movable stage can be a dither generator or an oscillator that scans, dithers, or oscillates the deflection grid 154. In this embodiment, the movable stage 152 translates, dithers, or oscillates the deflection grid 154 in a direction that is perpendicular to slots in the deflection grid 154. The translation, dithering, or oscillation reduces or eliminates shadowing effects and improves the uniformity of the ion beam flux impacting the surface of the wafer 150.

In one embodiment, a magnet 170 or any source of magnetic field is positioned proximate to the deflection grid 154 and to the wafer 150 so that a magnetic field is generated in the region between the deflection grid 154 and the wafer 150. The magnetic field traps at least a portion of the electrons that are located in the region proximate to the wafer 150.

In one embodiment, an electrode 172 is positioned proximate to the deflection grid 154 that absorbs at least a portion of the electrons generated when the dopant ions impact the surface of the wafer 150. In some of these embodiments, the electrode 172 is at substantially the same potential as the deflection grid 154.

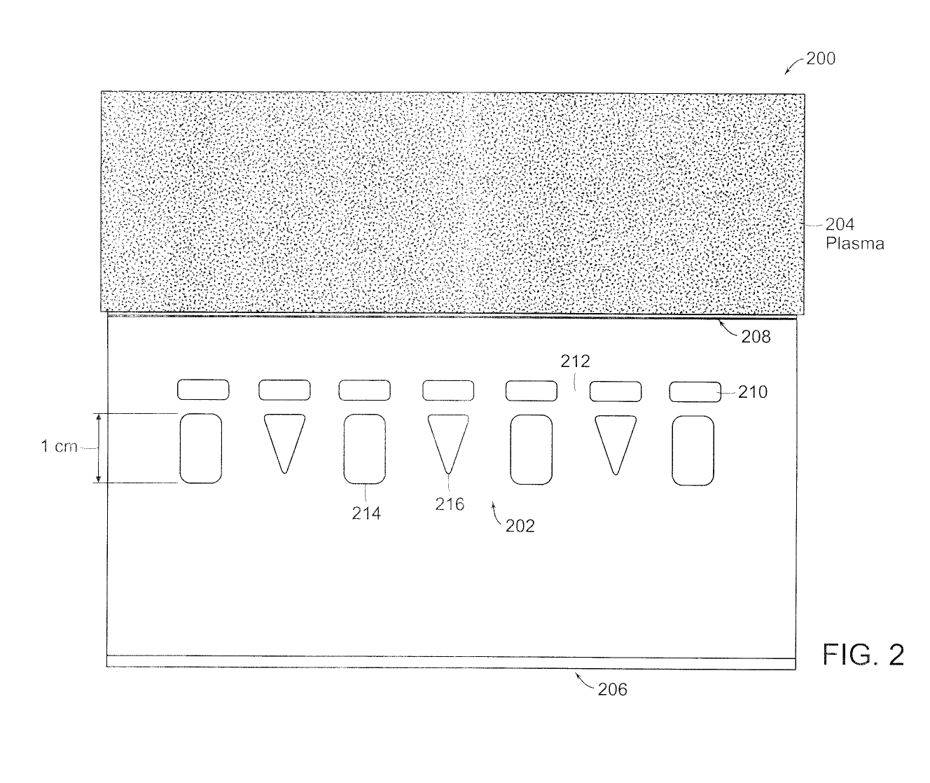

FIG. 2 illustrates a schematic diagram 200 of a deflection grid 202 according to the present invention. The schematic diagram 200 shows a deflection grid 202 according to the present invention that is positioned between the plasma 204 and the wafer 206. The deflection grid 202 is positioned proximate to the edge of the plasma sheath 208.

The deflection grid 202 includes a top section 210 that defines apertures 212 for passing ions from the plasma 204 through the deflection grid 202. In one embodiment, the dimensions of the apertures 212 are chosen to keep the plasma sheath 208 relatively flat under normal operating conditions. Also, in one embodiment, the dimensions of the apertures 212 are chosen to reduce or minimize the angular distribution of ions emerging from the top section 210. The thickness of the top section 210 is typically chosen so that it has a thermal mass which is sufficient to prevent the deflection grid 202 from distorting. The voltage applied to the top section 210 defines the ion implant energy. In one exemplary bias condition, the plasma sheath 208 is at ground potential and the top section 210 is biased at −1 kV.

The deflection grid 202 also includes a first 214 and second plurality of bipolar deflectors 216 that spatially alternate. The first 214 and second plurality of bipolar deflectors 216 are essentially electrostatic deflectors. The term “bipolar deflector” is used to indicate that the first 214 and second plurality of deflectors 216 is biased with alternating positive and negative voltages. That is, one of the first 214 and the second plurality of bipolar 216 deflectors is biased with a positive voltage and the other of the first 214 and the second plurality of bipolar deflectors 216 is biased with a negative voltage. For example, in the exemplary bias condition described herein, the first plurality of bipolar deflectors 214 is biased at +400V and the second plurality of bipolar deflectors 216 is biased at −400V.

In another embodiment, the deflection grid 202 is a monopolar ion deflection grid. In this embodiment, ions are deflected in only one direction. One skilled in the art will appreciate that there are many ways of achieving a monopolar ion deflection grid. For example, in one specific embodiment, the top section 210 is designed so that it blocks every other aperture between the first 214 and the second plurality of bipolar deflectors 216 so that ions are deflected in only one direction. In another specific embodiment, the first 214 and the second plurality of bipolar deflectors 216 form a structure that is specifically designed to deflect ions in only one direction. For example, in one embodiment, an insulator is positioned between the first 214 and the second plurality of bipolar deflectors 216 to form a structure that directs the electric field in the same direction for each aperture.

A fill factor of the deflection grid 202 can be selected to achieve a certain ion current at the surface of the wafer 206 or to limit the extent of the plasma 204 into the region between the deflection grid 202 and the wafer 206. The term “fill factor” is defined herein to mean the ratio of the open area of the top section 210 of the deflection grid 202 that passes dopant ions to the solid area of the top section 210 of the deflection grid 202 that blocks the ions. In some embodiments, the fill factor is selected to prevent formation of a plasma in the region between the deflection grid 202 and the wafer 206.

In the embodiment shown in FIG. 2, the deflection grid geometry is flat. Flat grid geometries are usually desirable because they provide a uniform ion path length, simplify voltage control, and are easier and less expensive to manufacture. However, it is understood that numerous grid geometries and numbers of grids can be used with the present invention. In the various embodiments, the cross section of the deflection grid 202 is chosen to be mechanically rigid enough so as to prevent the deflection grid 202 from distorting during normal operating conditions.

In one embodiment, the deflection grid 202 is formed of a non-metallic material or from a metallic material that is completely coated with a non-metallic material. For example, the deflection grid 202 can be formed of doped silicon (poly or single crystal), silicon carbide, and silicon coated aluminum. Such materials work well with hydride and fluoride chemistries.

The area of the deflection grid 202 is typically greater than or equal to the area of the wafer 206 being implanted. In one embodiment, the region between the deflection grid 202 and the wafer 206 is pumped to a lower pressure than the pressure of the plasma source 102 (FIG. 1) in order to prevent scattering of ions in the region caused by collisions with background dopant gas molecules. Also, in one embodiment, the region between the deflection grid 202 and the wafer 206 is pumped to a lower pressure than the plasma source 102 in order to prevent formation of a plasma in the region between the deflection grid 202 and the wafer 206.

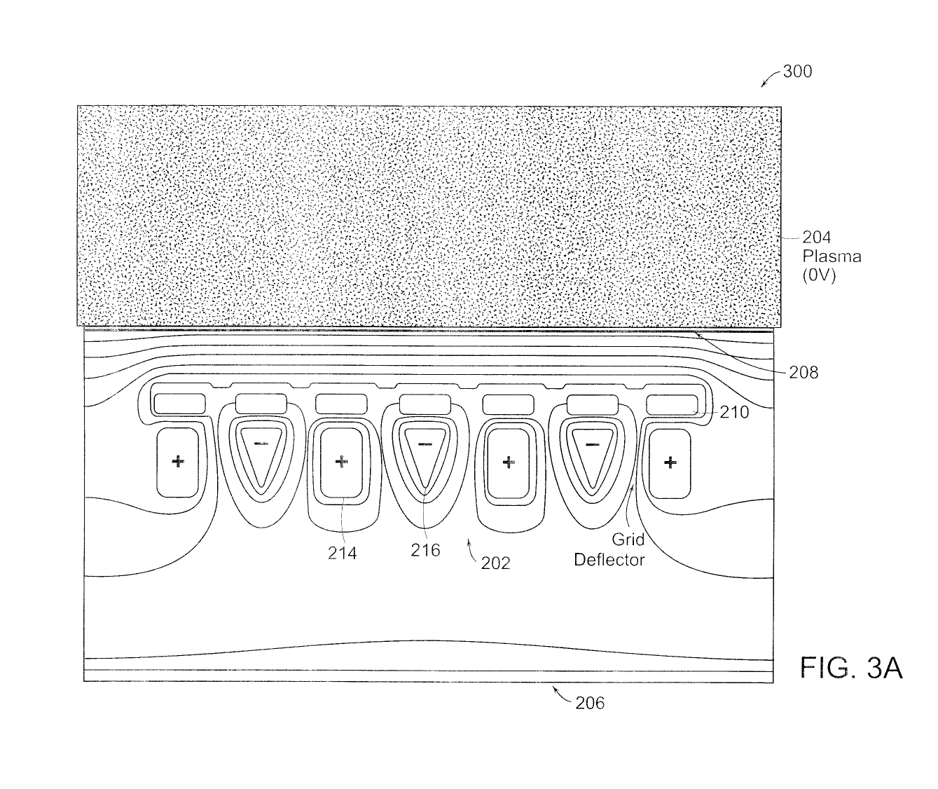

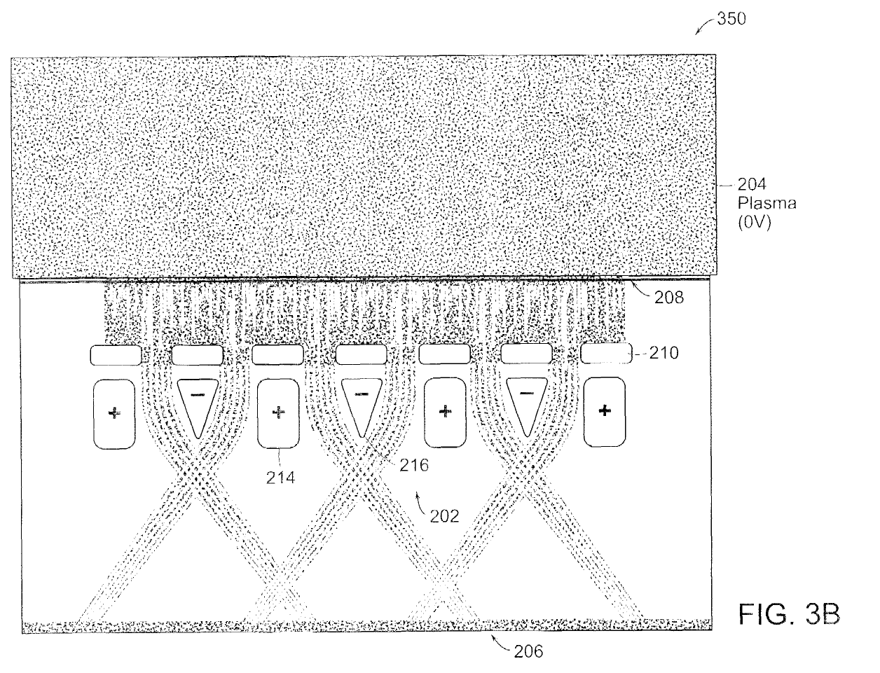

FIG. 3A illustrates simulated potential distributions 300 for the deflection grid 202 described in connection with FIG. 2. The plasma 204 and the plasma sheath 208 are at ground potential. The top section 210 of the deflection grid 202 and the wafer 206 are both biased at −1 kV. The first plurality of bipolar deflectors 214 is biased at +400V and the second plurality of bipolar deflectors 216 is biased at −400V. Therefore, the total voltage applied to the first plurality of bipolar deflectors 214 is −0.6 kV and the total voltage applied to the second plurality of bipolar deflectors 216 is −1.4 kV.

FIG. 3B illustrates simulated ion trajectories 350 corresponding to the simulated potential distributions 300 for the deflection grid 202 described in connection with FIG. 3A. The simulated ion trajectories 350 indicate that ions are extracted from the plasma 204 through the top section 210 of the deflection grid 202 at an energy that is defined by the potential applied to the top section 210. The ions are then deflected at angles that are proportional to the voltage applied to the first 214 and second plurality of bipolar deflectors 216. In many practical embodiments, at least one of the platen 148 (FIG. 1) supporting the wafer 206 being implanted and the defection grid 202 are scanned, oscillated, or dithered to improve uniformity of the ion flux at the surface of the wafer 206.

The data from the simulated ion trajectories 350 indicate that deflection angles of 33.9°±1.9° were obtained when the total voltage applied to the first plurality of bipolar deflectors 214 is −0.6 kV and the total voltage applied to the second plurality of bipolar deflectors 216 is −1.4 kV. The data indicate that the deflection grid 202 described in connection with FIG. 3A can achieve deflection angles that are in the range of at least 0-30 degrees.

Referring to FIGS. 1-3, in operation, the plasma source 102 of the plasma doping apparatus 100 is evacuated to high vacuum. The dopant gas is then injected into the plasma source 102 by the proportional valve 124 and exhausted from the process chamber 104 by the vacuum pump 132. In one embodiment, the dopant gas is symmetrically injected into the plasma source 102 and symmetrically pumped out of the process chamber 104. The gas pressure controller 136 is used to maintain the desired gas pressure for a desired dopant gas flow rate and exhaust conductance.

The RF power supply 118 generates a RF signal that is applied to the RF antennas 114, 116. In some embodiments, one of the planar coil antenna 114 and the helical coil antenna 116 is a parasitic antenna and the parasitic antenna is tuned in order to improve or maximize the uniformity of the plasma. In some embodiments, the RF source 118 generates a relatively low frequency RF signal. Using a relatively low frequency RF signal will minimize capacitive coupling and, therefore will reduce sputtering of the chamber walls and any resulting contamination. For example, in these embodiments, the RF power supply 118 generates RF signals below 27 MHz, such as 400 kHz, 2 MHz, 4 MHz or 13.56 MHz.

The RF current in the RF antennas 114, 116 induces RF currents into the plasma source 102. Electromagnetic fields induced by the RF currents in the RF antennas 114, 116 couple through at least one of the dielectric material forming the first section 106 and the dielectric material forming the second section 108 and then into the plasma source 102. The electromagnetic fields induced in the plasma source 102 excite and ionize the dopant gas molecules. Plasma ignition occurs when a small number of free electrons move in such a way that they ionize some dopant gas molecules. The ionized dopant gas molecules release more free electrons that ionize more gas molecules. The ionization process continues until a steady state of ionized gas and free electrons are present in the plasma.

Plasma ignition is difficult for some dopant gases, such as diborane in helium (15% B2H6 in 85% He). For these gases, it is desirable to use a strike gas to initiate the plasma. In one embodiment, a strike gas, such as argon (Ar) is controllably introduced into the process chamber 104 at a predetermined time by opening and then closing the burst valve 144. The burst valve 144 passes a short high-flow-rate burst of strike gas into the plasma source 102 in order to assist in igniting the plasma.

The plasma 204 is confined in the plasma chamber 102 by the deflection grid 154. The top section 158, 210 of the deflection grid 154, 202 and the wafer 150, 206 are biased so that dopant ions are extracted from the plasma 204 through the top section 158, 210. The first 214 and second plurality of bipolar deflectors 216 are biased at voltages that deflect the extracted ions at an angle that is proportional to the voltage difference between the first 214 and second plurality of bipolar deflectors 216. The voltages that bias the first 214 and second plurality of bipolar deflectors 216 are chosen so that the deflected ions impact the wafer 150, 206 at the desired non-normal angle of incidence.

In one embodiment of the present invention, the ion implants are performed with at least two different implant angles. That is, in this embodiment, a single multi-step ion implant is performed that implants ions with at least two different implant angles. It is desirable to perform such multi-step ion implant with a plurality of different implant angles in order to form some three-dimensional electronic structures. The plasma doping apparatus of the present invention can perform multi-step ion implants with at least two different implant angles by simply varying the voltage applied to the first 214 and second plurality of bipolar deflectors 216 as a function of time during the ion implant.

Most of the extracted dopant ions impact the wafer 150, 206 with an energy that is proportional to sum of the voltage applied to the top section 158, 210 of the deflector grid 154, 202 and the plasma potential. There may be some relatively low energy thermal ions that are present in residual plasma existing between the deflection grid 154, 202 and the wafer 150, 206. These ions are trapped between the deflection grid 154, 202 and the wafer 150, 206 and generally do not impact the wafer 150, 206. Many of the secondary electrons that are generated by ions impacting the wafer 150, 206 are absorbed by the positive potential of the ions. Electrons above the top section 158, 210 are quickly repelled by the negative voltage. When the bias voltage is extinguished, the plasma diffuses through the apertures in the top section 158, 210 and neutralizes charge on the surface of the wafer 150, 206.

One advantage of the present invention is that the non-normal angle of incidence at which the ions impact the surface of the wafer 150, 206 can be easily adjusted for a specific application by simply changing the voltage difference applied to the first 214 and second plurality of bipolar deflectors 216. Precisely controlling the non-normal angle of incidence at which the ions impact the surface of the wafer 150, 206 is important for numerous applications. For example, relatively low angles of incidence are required for some source drain extension implants for devices that use a diffusionless annealing process. Precise angles of incidence are required to perform side-wall doping for some devices that have trench and barrier structures and for some FinFET devices.

The non-normal angle of incidence at which the ions impact the surface of the wafer 150, 206 can also be chosen to achieve certain ion implant parameters. For example, the non-normal angle of incidence at which the ions impact the surface of the wafer 150, 206 can be chosen to achieve a predetermined lateral straggle of dopant ions in the wafer 150, 206. Also, the non-normal angle of incidence at which the ions impact the surface of the wafer 150, 206 can be chosen to achieve a predetermined channeling of dopant ions in the wafer 150, 206.

In one embodiment, at least one of the deflection grid 154, 202 and the wafer 150, 206 are biased by pulsing the at least one of the deflection grid 154, 202 and the wafer 150, 206 at a pulse frequency. In embodiments that include movable stages 174 such as, translation stages, oscillators, and/or dither generators that are mechanically coupled to at least one of the deflection grid 154, 202 and the wafer 150, 206, the pulse frequency of the bias voltage can be chosen to be proportional to the scan velocity, dither frequency, or oscillation frequency of the movable stage 152.

In some embodiments, the wafer 150, 206 is biased to a potential that at least partially neutralizes charge on or proximate to the wafer 150, 206. Also, in some embodiments, the wafer 150, 206 is biased to a potential that is positive with respect to the deflection grid 154, 202 in order to contain secondary electrons. Furthermore, in some embodiments, the deflection grid 154, 202 is periodically grounded so as to at least partially neutralize charge on or proximate to the wafer 150, 206.

### Equivalents

While the present teachings are described in conjunction with various embodiments and examples, it is not intended that the present teachings be limited to such embodiments. On the contrary, the present teachings encompass various alternatives, modifications and equivalents, as will be appreciated by those of skill in the art, may be made therein without departing from the spirit and scope of the invention as defined by the appended claims.

What is claimed is:

1. A plasma doping apparatus comprising:
a) a chamber;
b) a plasma source that generates ions from a feed gas;
c) a platen positioned in the chamber adjacent to the plasma source, the platen supporting a wafer for plasma doping; and
d) a deflection grid comprising a first and second deflection electrode positioned in the chamber between the plasma source and the platen, the deflection grid deflecting ions with an angle that is proportional to a voltage difference between the first and the second deflection electrodes.

2. The plasma doping apparatus of claim 1 wherein the plasma source comprises at least one of an inductively coupled plasma source, a capacitively coupled plasma source, a toroidal plasma source, a helicon plasma source, a DC plasma source, a glow discharge plasma source, a remote plasma source, and a downstream plasma source.

3. The plasma doping apparatus of claim 1 wherein a distance between the deflection grid and the platen is chosen to improve a uniformity of ion flux at the wafer.

4. The plasma doping apparatus of claim 1 wherein both the deflection grid and the wafer are biased at substantially the same potential.

5. The plasma doping apparatus of claim 1 wherein the deflection grid and the wafer are biased at different potentials.

6. The plasma doping apparatus of claim 1 wherein the deflection grid comprises a plurality of deflection grids.

7. A plasma doping apparatus comprising:
a) a chamber;
b) a plasma source that generates ions from a feed gas;
c) a platen positioned in the chamber adjacent to the plasma source, the platen supporting a wafer for plasma doping; and
d) a deflection grid that is positioned in the chamber between the plasma source and the platen, the deflection grid comprising
i. a top section that defines apertures for passing the ions from the plasma source through the deflection grid, the top section extracting ions from the plasma source at an energy that is proportional to a voltage applied to the top section; and
ii. a first and second plurality of deflection electrodes that are biased at a first and second deflection voltage, respectively, the first and second plurality of deflection electrodes deflecting ions with an angle that is proportional to a voltage difference between the first and the second deflection voltage.

8. The plasma doping apparatus of claim 7 wherein the plasma source comprises at least one of an inductively coupled plasma source, a capacitively coupled plasma source, a toroidal plasma source, a helicon plasma source, a DC plasma source, a glow discharge plasma source, a remote plasma source, and a downstream plasma source.

9. The plasma doping apparatus of claim 7 wherein the first plurality of deflection electrodes is biased at a positive voltage and the second plurality of deflection electrodes is biased at a negative voltage.

10. The plasma doping apparatus of claim 7 wherein only one of the first and second plurality of deflection electrodes is biased.

11. The plasma doping apparatus of claim 7 wherein the deflection grid comprises a plurality of deflection grids.

12. The plasma doping apparatus of claim 7 further comprising a power supply that is electrically connected to the top section of the deflection grid wherein the power supply generates a pulsed waveform that extracts ions from the plasma source with an energy that is proportional to an amplitude of the voltage pulse.

13. The plasma doping apparatus of claim 7 further comprising an RF power supply that is electrically connected to the top section of the deflection grid wherein the RF power supply generates an RF signal that extracts ions from the plasma source with an energy that is proportional to an amplitude of the RF signal.

14. The plasma doping apparatus of claim 7 further comprising a DC power supply that is electrically connected to the top section of the deflection grid wherein the DC power supply generates a DC signal that extracts ions from the plasma source with an energy that is proportional to an amplitude of the DC signal.

15. The plasma doping apparatus of claim 7 wherein an area of the deflection grid is greater than or equal to an area of the wafer.

16. The plasma doping apparatus of claim 7 wherein at least some of the first and second plurality of deflection electrodes comprise rods formed of electrically conducting materials.

17. The plasma doping apparatus of claim 7 further comprising an electrode that is positioned proximate to the deflection grid, the electrode being at substantially the same potential as the deflection grid so that at least a portion of electrons generated by the wafer during plasma doping are absorbed by the electrode.

18. The plasma doping apparatus of claim 7 further comprising a translation stage that is coupled to the platen, the translation stage scanning the wafer in at least one direction.

19. The plasma doping apparatus of claim 7 further comprising at least one oscillator that is mechanically coupled to at least one of the deflection grid and the platen, the at least one oscillator dithering at least one of the deflection grid and the wafer.

20. A method of plasma doping comprising:
a) generating a plasma in a chamber from a dopant gas, the plasma containing dopant ions;
b) biasing a deflection grid with a voltage that attracts the dopant ions from the plasma and directs the dopant ions through apertures in the deflection grid; and
c) electrostatically deflecting the dopant ions traveling through the aperture at an angle that is determined by a voltage difference between two deflection electrodes so that the dopant ions impact a surface of a wafer at a non-normal angle of incidence.

21. The method of claim 20 wherein the electrostatically deflecting the dopant ions traveling through the aperture comprises biasing the two deflection electrodes with alternating positive and negative potentials.

22. The method of claim 21 further comprising adjusting amplitudes of at least one of the alternating positive and negative potentials to improve uniformity of the dopant ions impacting the surface of the wafer.

23. The method of claim 20 further comprising electrostatically deflecting the dopant ions traveling through the aperture at a second angle that is determined by a second voltage difference between the two deflection electrodes so that the dopant ions impact the surface of the wafer at a second non-normal angle of incidence.

24. The method of claim 20 further comprising adjusting the voltage difference applied between the two deflection electrodes so that the dopant ions impact the surface of the wafer at a desired non-normal angle of incidence.

25. The method of claim 20 further comprising adjusting the voltage difference between the two deflection electrodes so that the dopant ions achieve a desired lateral straggle of dopant ions in the wafer.

26. The method of claim 20 further comprising adjusting the voltage difference between the two deflection electrodes to reduce channeling of dopant ions into the wafer.

27. The method of claim 20 further comprising selecting a voltage that biases the deflection grid to achieve a predetermined ion energy.

28. The method of claim 20 further comprising periodically biasing the deflection grid to a potential that at least partially neutralizes charge on or proximate to the wafer.

29. The method of claim 20 further comprising biasing the wafer at a potential that is positive with respect to the deflection grid in order to contain secondary electrons generated by the wafer.

30. The method of claim 20 further comprising periodically grounding the deflection grid to at least partially neutralize charge on or proximate to the wafer.

31. The method of claim 20 further comprising absorbing electrons generated by the target with an electrode at ground potential.

32. The method of claim 20 further comprising applying a magnetic field in a region between the deflection grid and the wafer to trap at least a portion of electrons that are located proximate to the wafer.

33. The method of claim 20 further comprising dithering at least one of the deflection grid and the grating to improve uniformity of the dopant ions impacting the wafer.

34. The method of claim 20 further comprising translating at least one of the deflection grid and the grating to improve uniformity of the dopant ions impacting the wafer.

35. A method of performing multi-step plasma doping:
a) generating a plasma in a chamber from a dopant gas, the plasma containing dopant ions;
b) biasing a deflection grid with a voltage that attracts the dopant ions from the plasma and directs the dopant ions through apertures in the deflection grid; and
c) generating a first voltage difference between two deflection electrodes for a first time period, the first voltage difference causing dopant ions to impact a surface of a wafer at a first non-normal angle of incidence for the first time period; and
d) generating a second voltage difference between the two deflection electrodes for a second time period, the second voltage difference causing dopant ions to impact the surface of the wafer at a second non-normal angle of incidence during the second time period.
